(19) United States
(12) Patent Application Publication
(10) Pub. No.: US 2008/0237898 A1
(43) Pub. Date: Oct. 2, 2008

(54) SEMICONDUCTOR DEVICE, METHOD FOR MANUFACTURING THE SAME, HEAT SINK, SEMICONDUCTOR CHIP, INTERPOSER SUBSTRATE, AND GLASS PLATE

(76) Inventors: Yuji YANO, Tenri-shi (JP); Yasuki Fukui, Sakai-shi (JP); Koji Miyata, Yao-shi (JP)

Correspondence Address: NIXON & VANDERHYE, PC, 901 NORTH GLEBE ROAD, 11TH FLOOR, ARLINGTON, VA, 22203, US

(21) Appl. No.: 12/049,728

(22) Filed: Mar. 17, 2008

(30) Foreign Application Priority Data
Mar. 27, 2007 (JP) 2007-082921

(51) Int. Cl. H01L 23/34; H01L 21/56

(52) U.S. Cl. 257/796; 438/122; 257/E23.08; 257/E21.502

(57) ABSTRACT

A semiconductor device of the present invention includes: a laminate structure, including a semiconductor chip, partially sealed with a resin; and a stress relief section for relieving a stress during resin sealing, provided as a convex section including a plain top surface on an uppermost section of the laminate structure, the stress relief section being provided in an annular shape on a peripheral region of the uppermost section so as to come into contact with the sealing resin. This makes it possible to improve the manufacturing yield of the semiconductor device in which the member of the uppermost section is exposed.

This Nonprovisional application claims priority under 35 U.S.C. §119(a) on Patent Application No. 082921/2007 filed in Japan on Mar. 27, 2007, the entire contents of which are hereby incorporated by reference.

### FIELD OF THE INVENTION

The present invention relates to a resin-sealed semiconductor device. More particularly, the present invention relates to a semiconductor device which is sealed with a resin by a transfer mold technique.

### BACKGROUND OF THE INVENTION

In recent years, as electronic devices have been downsized and high performance, it is necessary that a semiconductor device be downsized and densified. When a semiconductor device is downsized and densified, a semiconductor chip generates large amount of heat during operation of the semiconductor device. Therefore, it is necessary to improve heat radiation, for stable operation of the downsized and densified semiconductor device.

A conventional semiconductor device aimed at a densified semiconductor device is exemplified by a semiconductor package disclosed in Japanese Unexamined Patent Publication, Tokukai, No. 2004-172157 (published on Jun. 17, 2004) (Patent Document 1). In the semiconductor package of Patent Document 1, a connection substrate having external connection terminals is die-bonded on the semiconductor chip with an adhesive. Also, the semiconductor package of Patent Document 1 is sealed with a resin in such a manner that the external connection terminals on the connection substrate are exposed.

The following describes a structure of a conventional semiconductor device in which surfaces of the external connection terminals are exposed in the sealing resin with reference to FIG. 9.

As illustrated in FIG. 9, a semiconductor chip 101 is mounted on a substrate 103 via an adhesion layer 117. The semiconductor chip 101 is connected to the substrate 103 by a wire 113. External connection terminals 119 are provided on a lower surface of the substrate 103 and electrically connected to the semiconductor chip 101 by wirings formed on the substrate 103, and the wire 113.

A wiring pattern 111 is formed on the semiconductor chip 101. The wiring pattern 111 is used for connecting the semiconductor chip 101 to the wire 113, and the semiconductor chip 101 to an external component. The wiring pattern 111 is covered with a solder resist 109 except for a portion to be connected with the external component. A plurality of external connection terminals 115 includes an exposed section of the wiring pattern 111 and the solder resist 109. Furthermore, while the plurality of the external connection terminals 115 is exposed, a region including a part where the wiring pattern 111 is connected to the wirings formed on the substrate 103 by the wire 113 is sealed with a sealing resin 105.

The above arrangement allows a plurality of semiconductor devices to be laminated, thereby resulting in that a semiconductor device can be downsized and densified.

Conventional semiconductor devices directed to improving in their heat radiation capability are exemplified and disclosed in Japanese Unexamined Patent Publication, Tokukai, No. 2004-207307 (published on Jul. 22, 2004) (Patent Document 2), Japanese Unexamined Patent Publication, Tokukaihei, No. 2-181956 (published on Jul. 16, 1990) (Patent Document 3), and Japanese Unexamined Patent Publication, Tokukaihei, No. 5-63113 (published on Mar. 12, 1993) (Patent Document 4). In any of these semiconductor devices of Patent Documents 2 through 4, a heat sink is provided on a semiconductor chip via an adhesion layer, and resin sealing is performed in such a manner that an upper surface of the heat sink is exposed.

The following describes the semiconductor device disclosed in Patent Document 4, in which the upper surface of the heat sink is exposed in the sealing resin.

As illustrated in FIG. 10, a semiconductor chip 101 is mounted on a die pad 121 via an adhesion layer 117, and the semiconductor chip 101 is connected to an inner lead 123 and an outer lead 125 by a wire 113.

A heat sink 107 is provided on the semiconductor chip 101 via an adhesion layer. The heat sink 107, at a center thereof, includes a protruding part, and the protruding part is bonded to the semiconductor chip 101 by the adhesion layer 117.

These structures are sealed with a sealing resin 105, except that (i) a surface of the die pad 121, opposite to a surface bonded to the semiconductor chip 101, and (ii) a surface of the heat sink 107, opposite to a surface bonded to the semiconductor chip 101, are exposed in the sealing resin 105.

With the arrangement, it is possible to improve heat radiation efficiency of the heat sink of the semiconductor device of FIG. 10. This makes it possible to improve the heat radiation of the semiconductor chip inside the semiconductor device.

However, in a manufacturing process of a semiconductor device whose upper surface is exposed, as typified by the semiconductor device of FIG. 9 or 10, the following problems are caused.

When the resin sealing is performed by a transfer mold technique, a mold compresses a top surface of an uppermost section (the solder resist 109 or the heat sink 107) to be exposed in the sealing resin.

If a force by which the mold compresses the top surface of the uppermost section is small, then the sealing resin 105 runs over the top surface of the uppermost section. In the semiconductor device of FIG. 9, if the sealing resin 105 runs over the external connection terminals 115, then connection may become incomplete when other semiconductor devices are laminated. Also, in the semiconductor device of FIG. 10, if the resin 105 runs over the top surface of the heat sink 107 so that the exposed area of the heat sink 107 is reduced, the heat radiation efficiency is reduced.

On the other hand, if a force by which the mold compresses the top surface of the uppermost section is excessive, then a great force is entirely applied to the laminate structure in the mold. This causes a deformation or cracks of each constituent member including the semiconductor chip 101.

Whether or not the sealing resin runs over the top surface of the uppermost section is determined by pressure that the mold compresses the top surface of the uppermost section (force per unit area). If the pressure is greater than a certain force, then no sealing resin runs over the top surface of the uppermost section.

A force, applied to the entire laminate structure in the mold during resin sealing, is equal to a product of the pressure and an area where the top surface of the uppermost section comes in contact with the mold. Accordingly, the larger the contact area of the top surface of the uppermost section and the mold is, the greater the force applied to the entire laminate structure becomes. In other words, the smaller the contact area of the top surface of the uppermost section and the mold is, the smaller the force applied to the entire laminate structure becomes.

In the semiconductor device of FIG. 9 or 10, when an area of the uppermost section is small, an exposed area of the solder resist 109 (external connection terminals 115) or the heat sink 107 becomes small. This causes (i) a size of other connectable semiconductor devices to be limited, or (ii) the heat radiation efficiency to be reduced, or the like. Ultimately, the member of the uppermost section does not sufficiently work. To put it differently, if the area of the uppermost section is reduced in order to reduce the force applied to the entire laminate structure during resin sealing, then improvement of performances of the semiconductor device (high efficiency by a multilayer structure, and/or improvement of the heat radiation capability) is prevented. This is not a practical method, accordingly.

Also, in the semiconductor device described in Patent Document 1, when the resin sealing is performed by the transfer mold technique, the entire top surface of the uppermost section exposed in the sealing resin directly comes in contact with the mold. Therefore, in order to prevent the sealing resin from running over the top surface of the uppermost section, an enormous force is applied from the mold to the entire laminate structure during resin sealing. The external connection terminals are provided on the connection substrate, thereby resulting in that the area exposed in the sealing resin (the area coming in contact with the mold) includes concavity and convex. However, this is not sufficient to reduce the pressure applied from the mold to the semiconductor chip. Accordingly., it is difficult to prevent cracks of the semiconductor chip, which are caused during resin sealing.

Similarly, in the semiconductor devices described in Patent Documents 2 through 4, when the resin sealing is performed by the transfer mold technique, the uppermost section exposed in the sealing resin directly comes in contact with the mold. Therefore, in order to prevent the sealing resin from running over the top surface of the uppermost section during resin sealing, a great force is applied from the mold to the laminate structure including the uppermost section. Concavity and convex are formed on the top surface of the heat sink in order to improve the heat radiation capability, but this is not enough to reduce the area coming in contact with the mold. Accordingly, it is difficult to avoid the cracks of the semiconductor chip caused during resin sealing.

If the pressure by which the mold compresses the laminate structure is arranged to be small so that the force applied from the mold to the entire laminate structure is reduced during resin sealing, then the top surface of the uppermost section does not so tightly come into contact with the inside of the mold. If the top surface of the uppermost section does not so tightly come into contact with the inside of the mold, then it is obvious that the resin runs over the top surface of the uppermost section.

Consequently, according to the method of reducing the pressure of the mold during resin sealing so as to prevent the cracks of the semiconductor chip, at least the following problems arise. Specifically, the heat radiation capability is reduced in the case where the member of the uppermost section is the heat sink. The connection to the external component becomes difficult in the case where the member of the upper most section is arranged as shown in Patent Document 1 or in FIG. 9.

As described above, when the conventional semiconductor device is sealed with the resin by the transfer mold technique, the member of the uppermost section can be exposed. However, there is not enough consideration on damages (cracks) to the semiconductor device during resin sealing, so that sufficiently high manufacturing yield cannot be attained.

The present invention is made in view of the problems discussed above. An object of the present invention is to improve the manufacturing yield of the semiconductor device in which the member of the uppermost section is exposed.

### SUMMARY OF THE INVENTION

In order to achieve the above object, a semiconductor device of the present invention includes: a laminate structure including a semiconductor chip, partially sealed with a resin; and stress relief section for relieving a stress during resin sealing, provided as a convex section including a plain top surface on an uppermost section of the laminate structure, the stress relief section being provided in an annular shape on a peripheral region of the uppermost section so as to come into contact with the sealing resin.

When a semiconductor device is sealed with a resin by a transfer mold technique, whether or not the sealing resin runs over a top surface of an uppermost section depends on pressure by which a mold compresses the top surface of the uppermost section (force per unit area). If the pressure is greater than a certain force, then no sealing resin runs over the top surface of the uppermost section.

A force, applied to the entire laminate structure in the mold during resin scaling, is equal to a product of the pressure and an area where the top surface of the uppermost section comes in contact with the mold. Accordingly, the larger the contact area of the top surface of the uppermost section and the mold is, the greater the force applied to the entire laminate structure becomes. In other words, the smaller the contact area of the top surface of the uppermost section and the mold is, the smaller the force applied to the entire laminate structure becomes.

With the arrangement, the stress relief section is provided in an annular (ring) shape on a peripheral region of the uppermost section of the laminate structure. The “peripheral region of the uppermost section” means, in the top surface of the uppermost section, a ring-shaped region extending from its periphery to a slightly inner side of the periphery.

As such, when the resin sealing is performed, the mold comes into contact only with the stress relief section whose area is much smaller than that of the uppermost section of the laminate structure.

In view of this, with the arrangement, even if the mold compresses the top surface of the uppermost section in such a manner that the pressure of greater than a certain level is applied to the top surface of the uppermost section, the force applied to the entire laminate structure can be drastically reduced because the area where the laminate structure comes into contact with the mold is extremely small.

As a result, this can prevent damages to the laminate structure in the manufacturing process of the semiconductor device (resin sealing process), especially damages to the laminate structure which are caused when a strong force is applied to the laminate structure (for example, cracks of the semiconductor chip).

Moreover, the stress relief section is provided in the annular shape on the peripheral region of the uppermost section of the laminate structure. This, during resin sealing, allows the force applied from the mold to the entire laminate structure to be drastically reduced, but this does not mean that the pressure causing the mold to compress the ring-shaped stress relief section (the force, per unit area, causing the stress relief section to be compressed) is reduced. On this account, it is restrained that the resin runs over a part which is surrounded by the stress relief section, in the uppermost section of the laminate structure. Thus, the part which is surrounded by the stress relief section, in the uppermost section of the laminate structure, is exposed in the sealing resin.

With the stress relief section, the force applied to the entire laminate structure is drastically reduced. As such, even if the force per unit area by which the mold compresses the stress relief section strongly to some extent, the damages to the laminate structure are not caused. Accordingly, the inside of the mold can more tightly come into contact with the stress relief section, thereby making it possible to further prevent the resin from running over the part which is surrounded by the stress relief section. Namely, in the uppermost section of the laminate structure, it is possible for the part which is surrounded by the stress relief section to be more surely exposed in the sealing resin.

In view of this, for example, in a case where a heat sink is used as a member of the uppermost section, it is possible to efficiently radiate heat generated during the operation of the semiconductor device. Also, for example, in a case where a wiring layer or an interposer substrate having an external connection terminal is used as the member of the uppermost section, another semiconductor device can be further laminated on the manufactured semiconductor device. Moreover, for example, in a case where a semiconductor chip or a transparent substrate provided on the semiconductor chip is used as the member of the uppermost section, it is possible to manufacture a semiconductor device including a light-emitting element or a light-receiving element.

Accordingly, the arrangement can attain improvement of manufacturing yield of the semiconductor device in which the member of the uppermost section is exposed.

In order to achieve the above object, a heat sink of the present invention includes a convex section, having an annular shape, including a plain top surface, the convex section being provided on a peripheral region of a top surface on the heat sink, the heat sink constituting an uppermost section of a laminate structure including a semiconductor chip, and radiating heat generated from the semiconductor chip.

If the heat sink including the above arrangement is applied as an uppermost section of a laminate structure which constitutes a semiconductor device to be sealed with a resin, then it is possible to manufacture a semiconductor device including the heat sink whose top surface is exposed in the uppermost section of the laminate structure. Consequently, this makes it possible to attain a semiconductor device which can efficiently radiate the heat generated from the semiconductor chip during the operation of the semiconductor device. Also, it is possible to improve the manufacturing yield of the semiconductor device having the high heat radiation efficiency.

In order to achieve the above object, a semiconductor chip of the present invention includes a convex section, having an annular shape, including a plain top surface, the convex section being provided on a peripheral region of a top surface of the semiconductor chip, the semiconductor chip constituting an uppermost section of a laminate structure.

If the semiconductor chip including the above arrangement is applied as an uppermost section of a laminate structure which constitutes a semiconductor device to be sealed with a resin, then it is possible to manufacture the semiconductor device including the semiconductor chip whose top surface is exposed in the uppermost section of the laminate structure. Consequently, this makes it possible to attain a semiconductor device including a light-receiving element or a light-emitting element on the semiconductor chip.

For example, if the light-emitting element and/or the light-receiving element are(is) provided on the semiconductor chip, then it is possible to provide a semiconductor device which can be used as a communication tool in an apparatus or a light source of a display device. Moreover, it is possible to improve the manufacturing yield of the semiconductor device including the light-emitting element and/or the light-receiving element.

In order to achieve the above object, an interposer substrate of the present invention includes a convex section, having an annular shape, including a plain top surface, the convex section being provided on a peripheral side region of a top surface of the interposer substrate, the interposer substrate, including an external connection terminal, constituting an uppermost section of a laminate structure including a semiconductor chip.

If the interposer substrate having the above arrangement is applied as an uppermost section of a laminate structure which constitutes a semiconductor device to be sealed with a resin, then it is possible to manufacture the semiconductor device including the interposer substrate whose top surface is exposed in the uppermost section of the laminate structure. Accordingly, this makes it possible to attain a semiconductor device, on which a plurality of semiconductor devices is laminated, by connecting another semiconductor device to the exposed external connection terminal. Moreover, it is possible to improve the manufacturing yield of the semiconductor device on which another semiconductor device is laminated.

In order to achieve the above object, a transparent plate of the present invention includes a convex section, having an annular shape, including a plain top surface, the convex section being provided on a peripheral region of a top surface of the transparent plate, the transparent plate constituting an uppermost section of a laminate structure including a semiconductor chip.

If the transparent plate having the above arrangement is applied as an uppermost section of a laminate structure which constitutes a semiconductor device to be sealed with a resin, then it is possible to manufacture the semiconductor device including the transparent plate which is provided on the semiconductor chip, and whose top surface is exposed in the sealing resin. For example, if a light-emitting element and/or light-receiving element are(is) provided on the semiconductor chip, then it is possible to attain a semiconductor device which can be used as a communication tool in an apparatus or a light source of a display device. Moreover, it is possible to improve the manufacturing yield of the semiconductor device including the light-emitting element and/or the light-receiving element.

In order to achieve the above object, a method of the present invention for manufacturing a semiconductor device, which includes a laminate structure including a semiconductor chip, comprises the step of sealing the laminate structure with a resin, while a stress relief section comes into contact with a top surface of a room inside a mold, the stress relief section including a plain top surface and being provided in an annular shape on a top surface of the laminate structure so as to come into contact with the resin.

In the arrangement, the top surface of the stress relief section has an area much smaller than that of the top surface of the uppermost section. This makes it possible to drastically reduce an area where the inside of the mold comes in contact with the laminate structure during resin sealing. As a result, it is possible to drastically reduce a force applied from the mold to the entire laminate structure during resin sealing.

As such, the advantages similar to those of the above semiconductor device can be attained.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1(a) is a plan view illustrating an arrangement of a semiconductor device in accordance with Embodiment 1.

FIG. 1(b) is a cross sectional view taken along line A-A′ of FIG. 1(a).

FIG. 1(c) is a cross sectional view illustrating a resin sealing process which is carried out during manufacturing the semiconductor device of FIG. 1(b).

FIG. 1(d) is a cross sectional view illustrating a case where troubles are caused in the resin sealing process for manufacturing the semiconductor device of FIG. 1(b).

FIG. 2(a) is a plan view illustrating an arrangement of a semiconductor device in accordance with Embodiment 2.

FIG. 2(b) is a cross sectional view taken along line C-C′ of FIG. 2(a).

FIG. 2(c) is a cross sectional view illustrating a resin sealing process which is carried out during manufacturing the semiconductor device of FIG. 2(b).

FIG. 3(a) is a plan view illustrating an arrangement of a semiconductor device in accordance with Embodiment 3.

FIG. 3(b) is a cross sectional view taken along line D-D′ of FIG. 3(a).

FIG. 3(c) is a cross sectional view illustrating a resin sealing process which is carried out during manufacturing the semiconductor device of FIG. 3(b).

FIG. 4(a) is a plan view illustrating an arrangement of a semiconductor device in accordance with Embodiment 4.

FIG. 4(b) is a cross sectional view taken along line E-E′ of FIG. 4(a).

FIG. 5(a) is a cross sectional view illustrating an arrangement of a semiconductor device in accordance with Embodiment 5.

FIG. 5(b) is a cross sectional view illustrating a resin sealing process which is carried out during manufacturing the semiconductor device of FIG. 5(a).

FIG. 6 is a cross sectional view illustrating an arrangement of a modified example of the semiconductor device of FIG. 5.

FIG. 7 is a cross sectional view illustrating an arrangement of another modified example of the semiconductor device of FIG. 5.

FIG. 8 is a cross sectional view illustrating an arrangement of a modified example of the semiconductor device of FIG. 1.

FIG. 9 is a cross sectional view illustrating an arrangement of a conventional semiconductor device.

FIG. 10 is a cross sectional view illustrating an arrangement of another conventional semiconductor device different from the one of FIG. 9.

### DESCRIPTION OF THE EMBODIMENTS

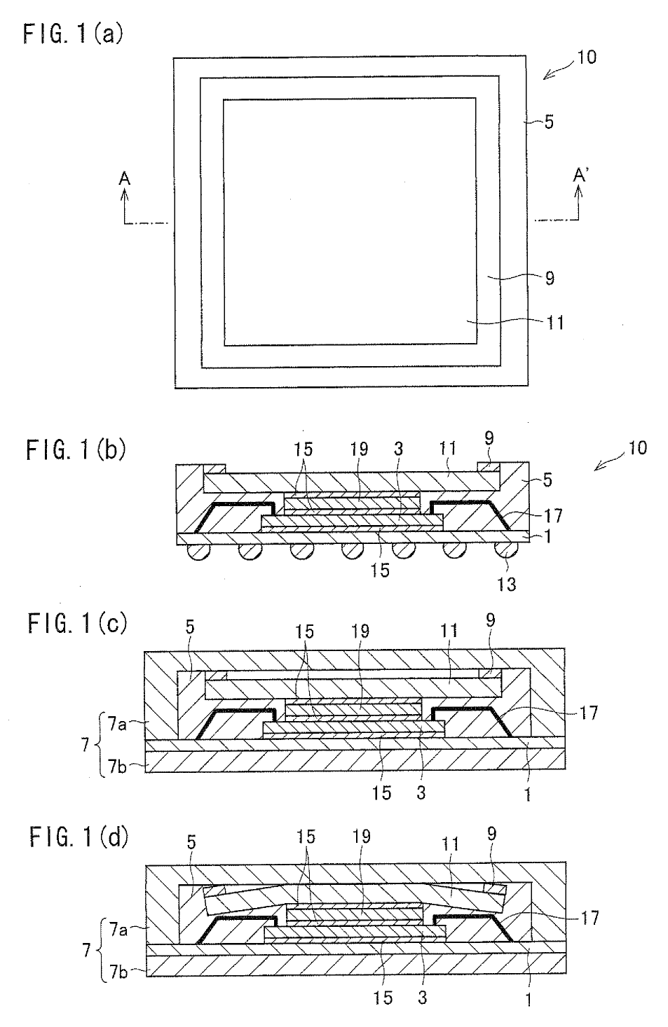

Embodiments of the present invention are described with reference to FIGS. 1 through 8. Through the following descriptions, each of members and components has a prescribed referential numeral. The members and components having the same referential numeral have the same name and function. Therefore, detailed explanations about the members and components, which are once explained, are not repeated.

In the description, a “peripheral region” means band-shaped region extending from sides constituting an area having a specified shape and an area slightly inside the sides. For example, in a case where the specified shape is a square, the “peripheral region” is a band-shaped region extending from four sides constituting the square to a slightly inner side of the four sides. The peripheral region is not limited to the one having a specified width and is not limited to the one similar to the above specified shape, provided that the peripheral region is a band-shaped region.

Furthermore, in the description, a “peripheral side region” means a ring-shaped region located inside the peripheral region and along the peripheral region. That is, the peripheral side region is not also limited to the one having a specified width and is not also limited to the one similar to the above specified shape, provided that the peripheral side region is a band shaped region.

### Embodiment 1

The following describes one embodiment of the present invention with reference to FIG. 1. FIG. 1(a) is a plan view illustrating an arrangement of a semiconductor device 10 of this embodiment. FIG. 1(b) is a cross sectional view taken along line A-A′ of FIG. 1(a). FIG. 1(c) is a cross sectional view illustrating a resin sealing process which is carried out during manufacturing the semiconductor device of FIG. 1(b).

As illustrated in FIG. 1(a), in a semiconductor device 10 of this embodiment, its side surface is sealed with a sealing resin 5. In a top surface of the semiconductor device 10, a heat sink 11 is exposed in the sealing resin 5. The heat sink 11 has a ring-shaped stress relief section 9 on a top surface of a peripheral region thereof, the stress relief section 9 having a convex cross sectional surface.

In the heat sink 11, a part which is surrounded by the ring-shaped stress relief section 9 is exposed in the sealing resin 5. That part of the heat sink 11 exposed in the sealing resin 5 highly effectively radiates heat. This allows the heat, generated from a semiconductor chip 3 during the operation of the semiconductor device 10, to be effectively radiated from the heat sink 11.

As illustrated in FIG. 1(b), the semiconductor device 10 includes: a substrate 1 on which external connection terminals 13 are provided; the semiconductor chip 3 electrically connected to the substrate 1 by a wire 17; a spacer 19 provided on the semiconductor chip 3; and the heat sink 11 on the spacer 19. The substrate 1, the semiconductor chip 3, the spacer 10, and the heat sink 11 are laminated so as to be bonded by respective adhesion layers 15. Such a laminate structure is formed by the substrate 1, the semiconductor chip 3, the spacer 10, and the heat sink 11, and its side surface is sealed with the sealing resin 5. In the peripheral region of the top surface of the heat sink 11, formed is a ring-shaped convex section including a plain top surface. This convex section serves as the stress relief section 9.

As illustrated in FIG. 1(c), during resin sealing by a transfer mold technique, the laminate structure is sealed with the resin while the stress relief section 9 is compressed by a mold 7.

Whether or not the sealing resin 5 runs over the top surface of the heat sink 11 depends on pressure (force per area unit) causing an upper mold 7a to compress a top surface of an upper most section (in this case, a top surface of the stress relief section 9). If the pressure is more than a certain level, then the sealing resin 5 does not run over the top surface of the heat sink 11.

A force applied, during resin sealing, to the entire laminate structure in the mold 7 is equal to a product of the pressure and an area where the stress relief section 9 comes into contact with the mold 7. Accordingly, the larger the area where the stress relief section 9 comes into contact with the mold 7 is, the greater the force applied to the entire stress relief section 9 becomes. In other words, the smaller the area where the stress relief section 9 comes into contact with the mold 7 is, the smaller the force applied to the entire laminate structure becomes.

As described above, the stress relief section 9 is provided only in the peripheral region of the heat sink 11. Therefore, the top surface of the stress relief section 9 has an area much smaller than that of the heat sink 11. That is, during resin sealing by the transfer mold technique, only the top surface of the stress relief section 9 comes into contact with an inner surface of the upper mold 7a (see FIG. 1(c)) is.

This makes it possible to largely reduce the area where the laminate structure comes into contact with the inner surface of the mold 7. This allows a large reduction in the force applied from the mold 7 to the entire laminate structure during the resin sealing.

Moreover, the stress relief section 9 is provided in an annular (ring) shape, and the resin sealing is performed while the stress relief section 9 tightly comes into contact with the mold 7. This allows the resin 5 not to run over a region in the heat sink 11, which region is surrounded by the stress relief section 9. That is, the heat sink 11 is exposed in the top surface of the semiconductor device 10.

With the arrangement, it is possible to improve the manufacturing yield of the semiconductor device 10 which can effectively radiate the heat via the heat sink 11, which heat is generated by the semiconductor chip 3 during the operation of the semiconductor device 10.

During resin sealing, the stress relief section 9 comes into contact with the upper mold 7a. The inner surface of the mold 7 is scratched and worn away because the inner surface comes into contact with the stress relief section 9 during the resin sealing. Especially, when the stress relief section 9 is made of a material having a great hardness, durability of the mold 7 is particularly lowered. For this reason, when the stress relief section 9 is made of a cushioning material, the abrasion of the mold 7 can be prevented. That is, the mold 7 becomes durable.

Also, when the stress relief section 9 is made of a cushioning material, the stress relief section 9 is deformed during resin sealing. This allows partial absorption of the pressure applied from the upper mold 7a to the laminate structure. Moreover, this allows the stress relief section 9 to tightly come into contact with the inner surface of the upper mold 7a. This makes it possible to surely prevent the sealing resin 5 from running over the part in the uppermost section of the laminate structure, which part is surrounded by the stress relief section 9.

In this way, according to this embodiment dealing with the semiconductor device 10, it is possible to improve the manufacturing yield of a semiconductor device 10 excellent in the heat radiation capability. In other words, even if the stress relief section 9 is formed not exactly in a specified shape due to slight nonevenness of process, intended effects (reduction in the pressure and prevention of the resin from running over) can be expected.

Moreover, when the stress relief section 9 is made of an elastic material, the force applied from the mold during resin sealing can be absorbed. Furthermore, this allows the upper mold 7a to more tightly come into contact with the stress relief section 9 during resin sealing. This allows the sealing resin 5 to be surely prevented from running over the part which is surrounded by the stress relief section 9. Also, this can prevent the abrasion of the mold 7, which is generated when the mold 7 comes into contact with the uppermost section during resin sealing.

The elastic material of which the stress relief section 9 is made is a material such as a polyimide or a solder resist. When the stress relief section 9 is made of the material such as a polyimide or a solder resist, it is easy to incorporate a process for forming a stress relief section 9 into a conventional wafer process. Therefore, the stress relief section 9 can be formed by using inexpensive materials with a simple process and a simple equipment.

As is described above, according to this embodiment dealing with the semiconductor device 10, it is possible to improve the manufacturing yield of the semiconductor device 10 excellent in the heat radiation removal capability.

### Embodiment 2

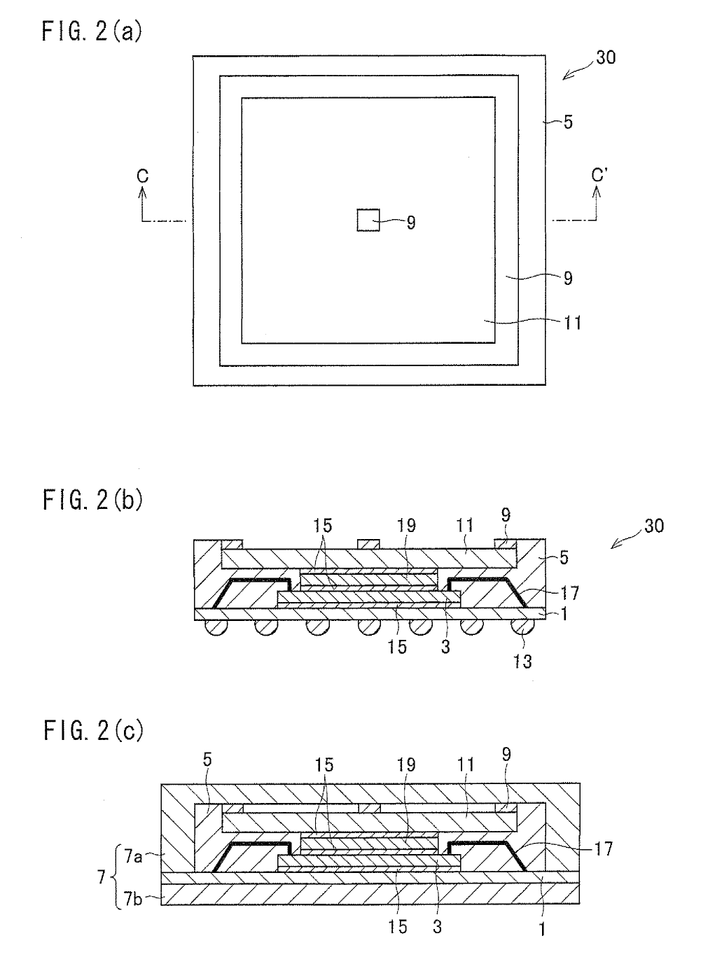

The following describes another embodiment of the present invention with reference to FIG. 2. FIG. 2(a) is a plan view illustrating an arrangement of a semiconductor device 30 of this embodiment. FIG. 2(b) is a cross sectional view taken along line C-C′ of FIG. 2(a). FIG. 2(c) is a cross sectional view illustrating a resin sealing process which is carried out during manufacturing the semiconductor device of FIG. 2(b).

As illustrated in FIGS. 2(a) and (b), in a semiconductor device 30 of this embodiment, its side surface is sealed with a sealing resin 5. The semiconductor device 30 includes, in its top surface, a heat sink 11 exposed in the sealing resin 5. Provided on the heat sink 11 is two stress relief sections 9 each having a convex cross sectional surface. An outer one of the two stress relief sections 9 is formed in a ring shape in such a manner to be adjacent to the sealing resin 5. In the heat sink 11, a part which is surrounded by the outer stress relief sections 9 is exposed in the sealing resin 5.

In the semiconductor device 30, the ring-shaped stress relief section 9 is provided on a peripheral region of the heat sink 11, so that damages to the laminate structure during resin sealing can be prevented in a manner similar to the semiconductor device 10.

As described above, the semiconductor device 30 of this embodiment includes the two stress relief sections 9. The semiconductor device 30 is different from the semiconductor device 10 in that the two stress relief sections 9 are provided at the peripheral region and its inner region.

As illustrated in FIG. 1(d), when a stress relief section 9 is provided only at the peripheral region, a center of the heat sink 11 may come into contact with the mold 7 due to nonevenness of process or other reason during resin sealing.

However, as illustrated in FIG. 2(c), an island shaped stress relief section 9 is formed at the center of the heat sink 11. This can avoid that the heat sink 11 comes into contact with the mold 7. An area of a top surface of the stress relief section 9 is not specifically limited) provided that it has such an area that can avoid that the heat sink 11 comes into contact with the mold 7. The area may be extremely small. This results in that the heat sink 11 can be prevented from coming into contact with the mold 7 while exposure efficiency (heat radiation efficiency) of the heat sink 11 is almost maintained. Therefore, it is preferable that an inner stress relief section 9 in the semiconductor device 30 be provided in an island shape at the center of the top surface of the heat sink 11. According to this configuration, since a stress relief section 9 whose top surface is extremely small is employed, it is possible avoid that the heat sink 11 comes into contact with the mold 7.

See Embodiment 1 as for particulars of the stress relief section 9 such as shape, function, and quality of material.

### Embodiment 3

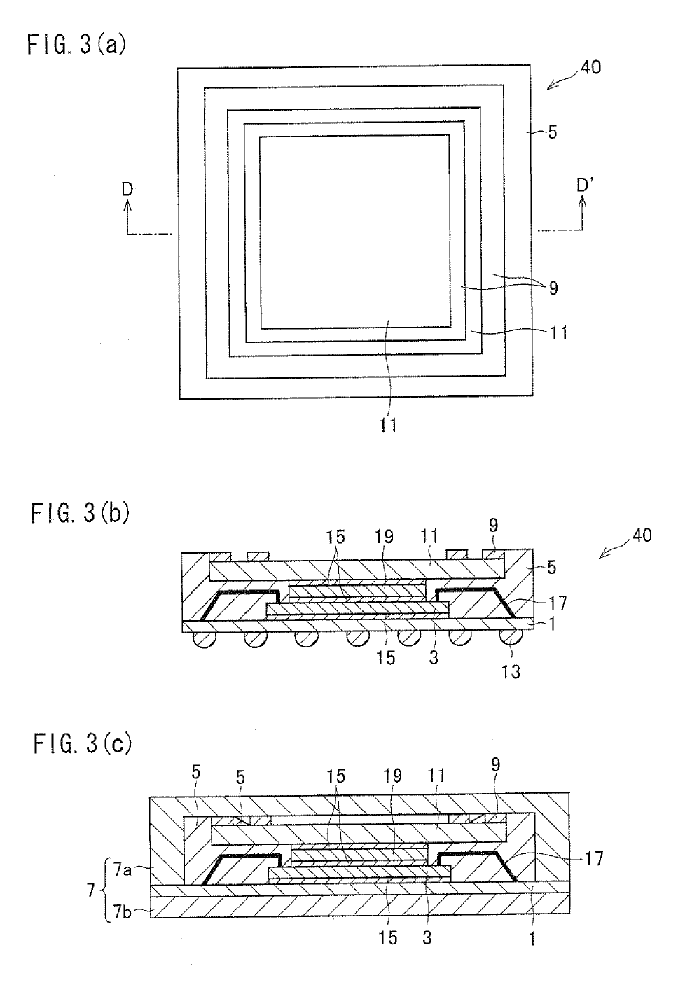

The following describes a further embodiment of the present invention with reference to FIG. 3. FIG. 3(a) is a plan view illustrating an arrangement of a semiconductor device 40 of this embodiment. FIG. 3(b) is a cross sectional view taken along line D-D′ of FIG. 3(a). FIG. 3(c) is a cross sectional view illustrating a resin sealing process which is required during manufacturing the semiconductor device of FIG. 3(b).

The semiconductor device 40 of this embodiment is a modified example of the semiconductor device 10 disclosed in Embodiment 1. Therefore, commonly used members are not to be explained.

As illustrated in FIGS. 3(a) and (b), the semiconductor device 40 is different from the semiconductor device 10 in that each of two stress relief sections 9 is provided in a ring shape. An inner stress relief section 9 is provided so as to be away from an outer stress relief section 9.

As illustrated in FIG. 3(c), the two ring-shaped stress relief sections 9 are provided so as to be away from each other. On this account, even if a resin 5 runs over inside the outer stress relief section 9, the resin 5 is caught by a gap space between the two stress relief sections 9. That is, even if the resin 5 runs over inside the outer stress relief section 9, the inner stress relief section 9 can further prevent the resin 5 from running over inside the inner stress relief section 9. This allows (i) the semiconductor device 40 to have a further improvement in the manufacturing yield and (ii) the top surface of the member of the uppermost section (heat sink 11) to be surely exposed.

In this way, it is possible to improve the manufacturing yield of a semiconductor device in which a member of the uppermost section is exposed.

See Embodiment 1 as for particulars of the stress relief section 9 such as shape, function, quality of material.

### Embodiment 4

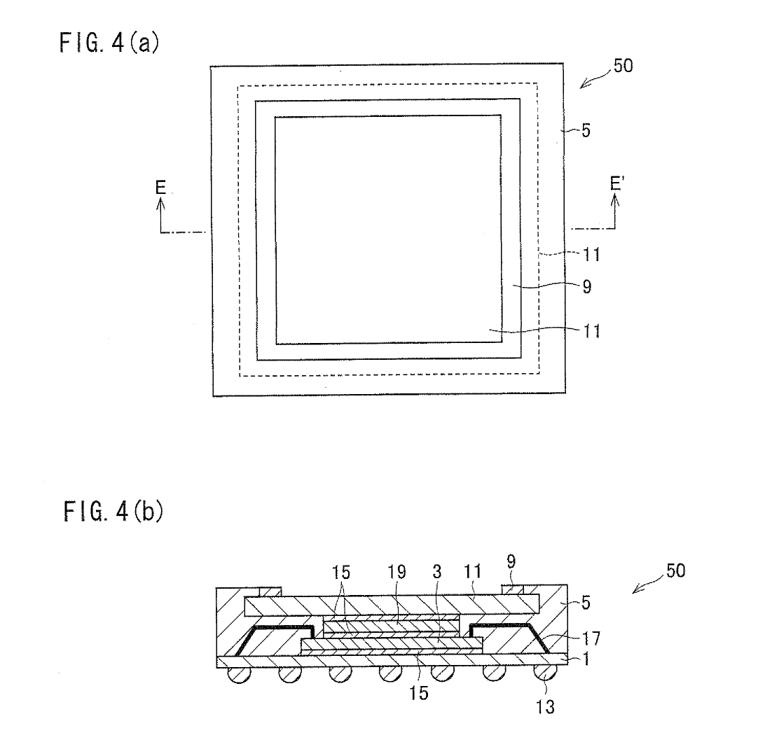

The following describes still a further embodiment of the present invention with reference to FIG. 4. FIG. 4(a) is a plan view illustrating a semiconductor device 50 of this embodiment. FIG. 4(b) is a cross sectional view taken along line E-E′ of FIG. 4(a).

The semiconductor device 50 of this embodiment is a modification of the semiconductor device 10 disclosed in Embodiment 1. Therefore, commonly used members are not to be explained.

As illustrated in FIG. 4(a), in the semiconductor device 50, its side surface is sealed with a sealing resin 5. The semiconductor device 50 includes, in its top surface, a heat sink 11 exposed in the sealing resin 5. The heat sink 11 has a ring-shaped stress relief section 9 including a convex cross sectional surface on a peripheral side region of a top surface thereof.

A configuration of the semiconductor device 50 has so much in common with that of the semiconductor device 10. Especially, the shape and function of the stress relief section 9 is the same as that of the semiconductor device 10. As such, see Embodiment 1 as for particulars of the stress relief section 9 such as shape and function.

The semiconductor device 50 is different from the semiconductor device 10 in that a periphery on the heat sink 11 is sealed with the resin 5. The stress relief section 9 of the semiconductor device 50 does not come into contact with the periphery of the heat sink 11. The stress relief section 9 of the semiconductor device 50 is provided more inside than that of the semiconductor device 10.

When the stress relief section 9 is provided so as to come into contact with the periphery of the uppermost section (heat sink 11) like the semiconductor device 10, a boundary surface between the resin 5 and a respective of the stress relief section 9 and the heat sink 11 becomes even and smooth (see FIG. 1(b)). When the boundary surface becomes even and smooth, the resin 5 and the laminate structure are not so strongly and tightly bonded. Therefore, if the semiconductor device receives an impact, the resin 5 is easily exfoliated from the laminate structure, so that the laminate structure becomes easily eroded because of moisture intrusion from the boundary surface.

As illustrated in FIG. 4(b), in the semiconductor device 50, the periphery of the heat sink 11 is scaled with the resin 5. That is, the stress relief section 9 is placed inside the periphery of the top surface of the heat sink 11. This allows the boundary surface to have a protrusion which extends on the heat sink 11. As such, even if the semiconductor device 50 receives some impacts, the laminate structure will not be exfoliated from the resin 5. Moreover, the boundary surface is not even and smooth, but has a hooked structure having the protrusion. This allows the laminate structure to be more tightly bonded to the resin 5. As a result, this can prevent the laminate structure from being eroded because of the moisture intrusion to the boundary surface.

### Embodiment 5

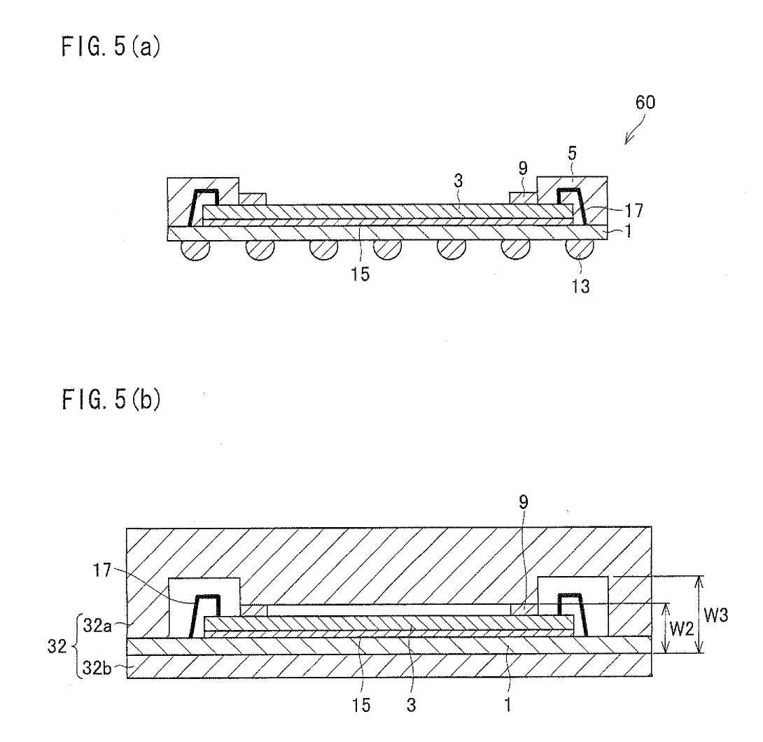

The following describes another embodiment of the present invention with reference to FIG. 5. FIG. 5(a) is a cross sectional view illustrating an arrangement of a semiconductor device 60. FIG. 5(b) is a cross sectional view illustrating a resin sealing process with the use of a transfer mold technique, in processes for manufacturing the semiconductor device 60 of this embodiment.

As illustrated in FIG. 5(a), a semiconductor device 60 of this embodiment includes: a substrate 1 on which external connection terminals 13 are provided; a semiconductor chip 3 electrically connected to the substrate 1 via a wire 17; a stress relief section 9 provided on the semiconductor chip 3; and a sealing resin 5 partially covering the substrate 1 and the semiconductor chip 3. The semiconductor chip 3 is bonded to the substrate 1 by an adhesion layer 15.

The stress relief section 9 is provided in a ring shape on the semiconductor chip 3 so as to come into contact with the sealing resin 5. A region on the semiconductor chip 3, which region is surrounded by the stress relief section 9, is exposed in the sealing resin 5. A periphery of the semiconductor chip 3 is sealed with the resin 5.

The semiconductor device 60 of this embodiment is different from the semiconductor devices 10, 30, and 40 in that the sealing resin 5 is provided so as to be higher than the stress relief section 9.

The wire 17 for connecting the semiconductor chip to the substrate 1 is provided so as to be higher than the stress relief section 9. The sealing resin 5 is provided higher than the stress relief section 9 so that the wire 17 is sealed with the resin 5.

Note that, because the semiconductor device 60 includes the stress relief section 9, the damages to the semiconductor chip 3 are to be similarly prevented.

Explained is a method for forming the sealing resin 5 so that the sealing resin 5 is higher than the stress relief section 9 with reference to FIG. 5(b).

As illustrated in FIG. 5(b), a mold 32 includes an upper mold 32a and a lower mold 32b. In the vicinity of either end, the upper mold 32a includes, in its top surface, concave portions. In other words, a void inside the mold 32 has two different levels in height. A portion whose height is W2 inside the mold 32 (a portion facing the stress relief section 9 and its inner portion, in the laminate structure) is low. On the other hand, a portion whose height is W3 inside the mold 32 (a portion facing an outer portion of the stress relief section 9 in the laminate structure) is high.

In the top surface of the upper mold 32a, either side of the portion of W2 in height comes into contact with the top surface of the stress relief section 9 with no space therebetween. As such, the sealing resin 5 injected from a filling opening does not go into inside the ring-shaped stress relief section 9, but fills only the portion of W3 in height inside the mold 32.

That is, in the top surface of the semiconductor chip 31, a region which is surrounded by the ring-shaped stress relief section 9 is exposed in the sealing resin 5. Moreover, the wire 17 can be thoroughly sealed with the sealing resin 5.

As described above, the stress relief section 9 has an area much smaller than that of the top surface of the uppermost section (semiconductor chip 3, in this case). As such, even if the mold 32 compresses the laminate structure strongly to some extent, the damages to the laminate structure (especially, to the semiconductor chip 3) are not to be caused. Accordingly, the mold 32 may compress the laminate structure strongly to some extent so that the top surface of the mold 32a more tightly comes into contact with the stress relief section 9. This can further prevent the resin 5 from going into inside the stress relief section 9.

The configuration of this embodiment can be preferably applied to a case where a light-emitting element and/or light receiving element are/is provided on the semiconductor chip 3. When a light-emitting element and/or a light-receiving element are/is provided in a portion which is exposed in the sealing resin 5, the sealing resin does not block off light emitted from the light-emitting element or light incident on the light-receiving element. Consequently, it is possible to provide a semiconductor device 60, which ensures insulation properties, including highly reliable light-emitting element and/or light-receiving element.

See Embodiment 1 as for details particulars of the stress relief section 9 such as shape, function, quality of material.

### Embodiment 6

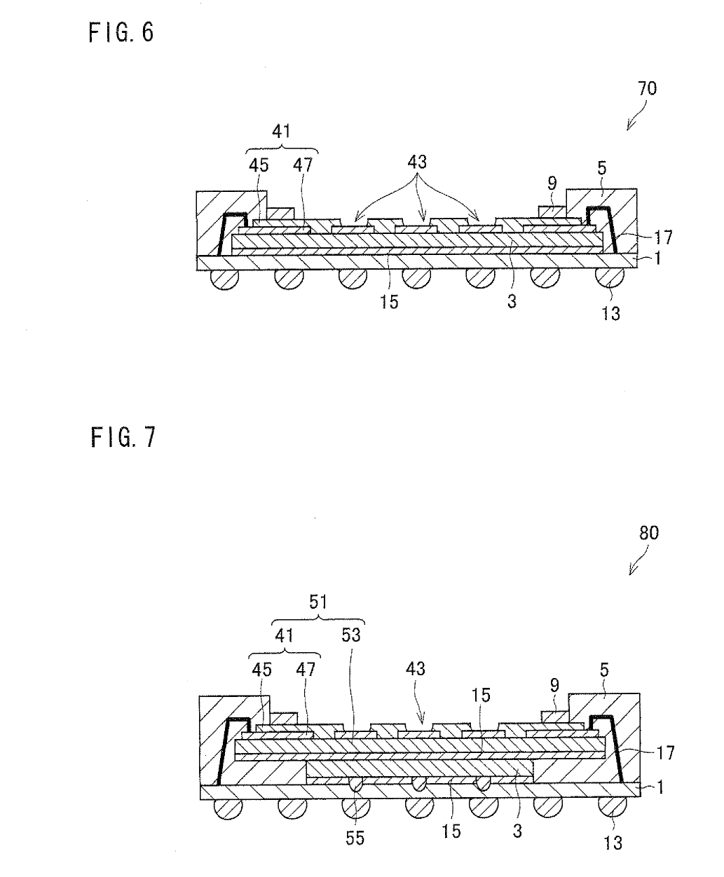

The following describes a further embodiment of the present invention with reference to FIG. 6. FIG. 6 is a cross sectional view illustrating an arrangement of a semiconductor device 70 of this embodiment.

As illustrated in FIG. 6, a semiconductor device 70 of this embodiment includes: a substrate 1 on which external connection terminals 13 are provided; a semiconductor chip 3 provided on the substrate 1; a wiring pattern 47 provided on the semiconductor chip 3; a solder resist 45 partially covering the wiring pattern 47; a stress relief section 9 provided on the solder resist 45; and a sealing resin 5 partially covering the semiconductor chip 3, the wiring pattern 47, and the solder resist 45.

With the arrangement, the semiconductor chip 3 is bonded to the substrate 1 via an adhesion layer 15. The substrate 1 is electrically connected to the semiconductor chip 3 by the wire 17 and the wiring pattern 47. Moreover, the solder resist 45 and the wiring pattern 47 constitute a wiring layer 41. In the wiring layer 41, a part where the wiring pattern 47 is exposed in the solder resist 45 works as an external connection terminal 43 on which other semiconductor devices are to be laminated. This is because in the wiring layer 41, a part which is surrounded by the stress relief section 9 is exposed in the sealing resin 5. On this account, this allows the part where the wiring pattern 47 is exposed in the solder resist 45 to be connected to external components (other semiconductor devices).

The semiconductor device 70 of this embodiment is different from the semiconductor device 60 of Embodiment 5 in that the wiring layer 41 including the external connection terminal 43 is provided at an uppermost section. The semiconductor device 70 is not largely different from the semiconductor device 60 in other arrangements. Especially, the stress relief section 9 has the same shape and functions.

In this way, as illustrated in FIG. 6, the semiconductor device 70 includes the stress relief section 9. With the arrangement, it is possible to prevent the damages to the laminate structure (cracks of the semiconductor chip 3) during resin sealing, and to improve the manufacturing yield of the semiconductor device 70 in which a member of the uppermost section is exposed (the wiring layer 41, in this case). According to this embodiment dealing with the semiconductor device 70, it is possible to attain a semiconductor device having a multilayer structure.

Moreover, the semiconductor device 70 of this embodiment may include two stress relief sections 9 in a manner similar to Embodiments 2 and 3. An inner stress relief section 9 may be provided anywhere on the solder resist other than a part where the external connection terminal 43 is provided. See Embodiments 2 and 3 as for particulars of the effects of the case where two stress relief sections 9 are provided.

When the stress relief section 9 is made of the solder resist, the stress relief section 9 can be simultaneously formed in a process for forming a wiring layer 41. This makes it possible to improve manufacturing efficiency and simplify the manufacturing process.

See Embodiment 1 as for particulars of the stress relief section 9 such as shape, function, quality of material.

### Embodiment 7

The following describes still a further embodiment of the present invention with reference to FIG. 7. FIG. 7 is a cross sectional view illustrating an arrangement of a semiconductor device 80 of this embodiment.

As illustrated in FIG. 7, a semiconductor device 80 of this embodiment includes: a substrate 1 on which external connection terminals 13 are provided; a semiconductor chip 3 electrically connected to the substrate 1 by a bump 55; a substrate 53 provided on the semiconductor chip 3; a wiring pattern 47 electrically connected to the substrate 1 by a wire 17; a stress relief section 9 provided on the wiring pattern 47; and a sealing resin 5 partially covering the substrate 1, a side surface of the semiconductor chip 3, a wiring layer 41, and the substrate 53.

With the arrangement, an adhesion layer 15 is provided respectively between the semiconductor chip 3 and the substrate 1, and between the semiconductor chip 3 and the substrate 53. An interposer substrate 51 is formed by the wiring layer 41 and the substrate 53. An external connection terminal 43 (the wiring pattern 47 exposed in a solder resist 45) is provided in a top section of the wiring layer 41. In the top section of the wiring layer 41, the external connection terminal 43, provided in a region which is surrounded by the stress relief section 9, is exposed in the sealing resin 5.

The semiconductor device 80 of this embodiment is different from the semiconductor device 70 of Embodiment 6 in that the wiring layer 41 and the substrate 53 constitute the interposer substrate 51, and the semiconductor chip 3 is electrically connected to the substrate 1 by the bump 55. That is, those semiconductor devices are different in the inner configuration, but have similar arrangement and function of the stress relief section 9, which are features of the present invention. Moreover, in either semiconductor devices, the external connection terminal 43 is exposed in the sealing resin 5.

The substrate 1 is electrically connected to the semiconductor chip 3 by the wire 17 and the wiring pattern 47. The solder resist 45 and the wiring pattern 47 constitute the wiring layer 41. In the wiring layer 41, a part where the wiring pattern 47 is exposed in the solder resist 45 works as the external connection terminal 43, on which other semiconductor devices are to be laminated. This is because in the wiring layer 41, the part which is surrounded by the stress relief section 9 is exposed in the sealing resin 5. This allows the part where the wiring pattern 47 is exposed in the solder resist 45 to be connected to external components (other semiconductor devices), as described above.

In this way, the semiconductor device 80 includes the stress relief section 9. With the arrangement, it is possible to prevent the damages to the laminate structure (especially, cracks of the semiconductor chip 3) during resin sealing, and to improve the manufacturing yield of the semiconductor device 80 in which a member of the uppermost section is exposed (the wiring layer 41, in this case). According to this embodiment of the semiconductor device 80, it is possible to attain a semiconductor device having a multilayer structure. Moreover, this can attain a highly reliable semiconductor device after mounting process.

The semiconductor device 80 may include two stress relief sections 9 in a manner similar to the semiconductor device 70. An inner stress relief section 9 may be provided anywhere on the solder resist other than a part where the external connection terminal 43 is provided. See Embodiments 2 and 3 as for particulars of the effects of the case where two stress relief sections 9 are provided.

Also, see Embodiment 1 as for particulars of the stress relief section 9 such as shape, function, quality of material.

### Embodiment 8

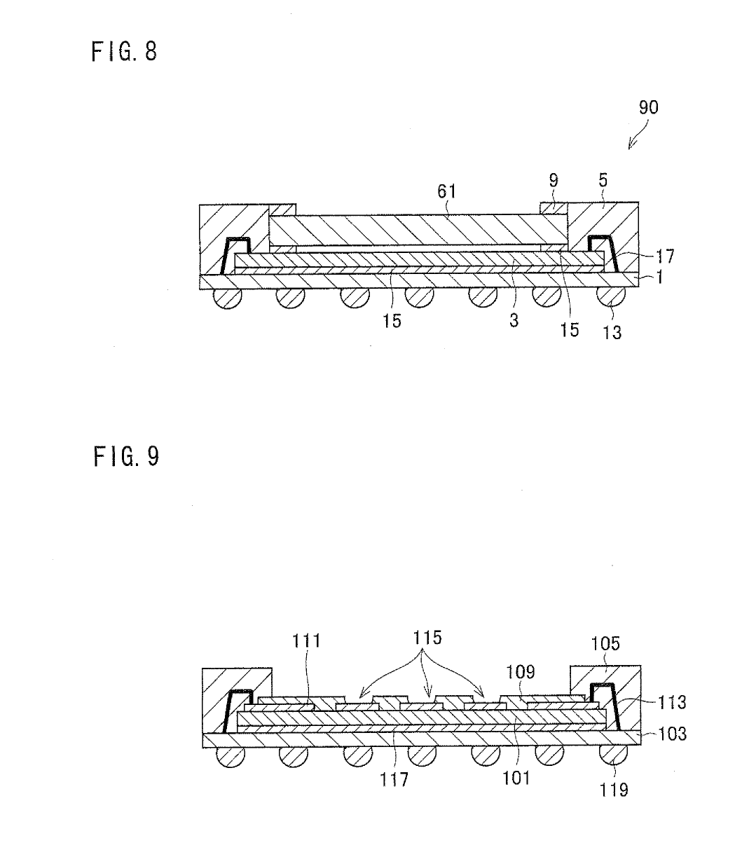

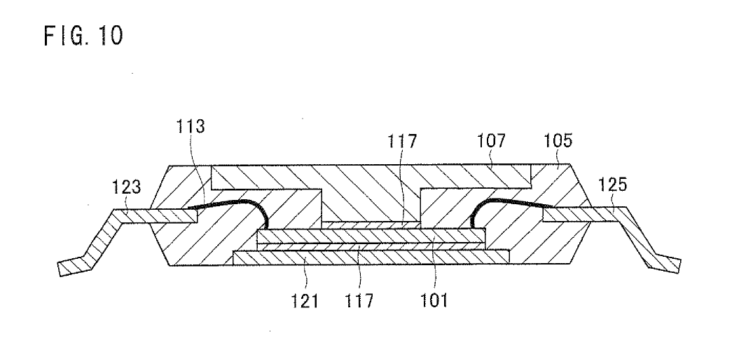

The following describes still further another embodiment of the present invention with reference to FIG. 8. FIG. 8 is a cross sectional view illustrating an arrangement of a semiconductor device 90 of this embodiment.

As described in FIG. 8, a semiconductor device 90 of this embodiment includes: a substrate 1 on which external connection terminals 13 are provided; a semiconductor chip 3 electrically connected to the substrate 1 by a wire 17; a glass plate 61 provided on the semiconductor chip 3; a stress relief section 9 provided on the glass plate 61; and a sealing resin 5 partially covering the substrate 1 and the semiconductor chip 3.

With the arrangement, an adhesion layer 15 is respectively provided between the substrate 1 and the semiconductor chip 3, and between the semiconductor chip 3 and the glass plate 61. The adhesion layer 15 which bonds the semiconductor chip 3 with the glass plate 61 is provided at either end of the glass plate 61, corresponding to a part where the stress relief section 9 is provided. In a top surface of the glass plate 61, a region which is surrounded by the ring-shaped stress relief section 9 is exposed in the sealing resin 5. The glass plate 61 covers a region on the semiconductor chip 3 corresponding to the exposed region in the top surface of the glass plate 61.

With the arrangement, the sealing resin 5 does not block off light emitted from the region on the semiconductor chip 3, so that the light is transmitted outside through the glass plate 6. On the other hand, the sealing resin 5 does not block off light from outside, so that the light is incident upon the region on the semiconductor chip 3 through the glass plate 6. That is, when a light-emitting element and/or light-receiving element are/is provided on the semiconductor chip 3, it is possible to attain the semiconductor device 90, which ensures insulation properties, including a highly reliable light-emitting element and/or light-receiving element. Also, it is possible to improve the manufacturing yield of the semiconductor device 90.

In the semiconductor device 90 of this embodiment, a top surface of the stress relief section 9 is as high as that of the sealing resin 5. Therefore, with the stress relief section 9 which has a mechanism of action similar to the one described Embodiment 1, it is possible to improve the manufacturing yield and expose the member of the uppermost section.

In a semiconductor device of the present invention, it is preferable that a periphery of the uppermost section of the laminate structure be sealed with the resin.

When a stress relief section is provided so as to come into contact with the periphery of the uppermost section, a boundary surface between the sealing resin and a respect of the uppermost section and the stress relief section is even and smooth. If the boundary surface between the sealing resin and the respect of the uppermost section and the stress relief section is even and smooth, the sealing resin is not tightly and strongly bonded to the laminate structure. Therefore, if the semiconductor device receives some impacts, the laminate structure is easily exfoliated from the sealing resin, so that the laminate structure becomes easily eroded because of moisture intrusion from the boundary surface.

However, with the arrangement, the periphery in the peripheral region of the uppermost section is sealed with the resin. This allows the boundary surface to have a protrusion which extends on the top surface of the uppermost section. Due to the protrusion of the boundary surface, the periphery of the uppermost section can be fixed from above. As such, even if the semiconductor device receives impacts to some extent, the laminate structure will not be exfoliated from the sealing resin. Moreover, the boundary surface is not even and smooth, but has a hooked shape having the protrusion. This allows the sealing resin to be more firmly bonded to the laminate structure. As a result, this can prevent the laminate structure from being eroded because of moisture intrusion to the boundary surface.

Consequently, this allows the semiconductor device to have an improvement in durability (reliability).

In the semiconductor device of the present invention, it is preferable that another stress relief section be further provided inside the stress relief section provided on the peripheral region of the uppermost section.

In a case where the stress relief section is provided only on the peripheral region, if the laminate structure is excessively compressed by a mold in order to prevent the resin from running over, the member of the uppermost section may be deformed. If the member of the uppermost section is deformed, the member of the uppermost section comes into contact with the mold. This causes the damage to the member of the uppermost section. As a result, a damaged part of the member of the uppermost section easily becomes eroded or the like.

For example, an inner stress relief section may be provided in an island shape at a center of the top surface of the uppermost section. In this case, the member of the uppermost section is prevented from being deformed without much reduction in an exposed area of the top surface of the present invention. It is restrained that the member of the uppermost section is deformed. This can prevent the mold from coming into contact with the member of the uppermost section.

Also, for example, when an inner stress relief section is formed in a ring shape so as to be away from an outer stress relief section, even if the sealing resin runs over inside the outer stress relief section, the inner stress relief section can further prevent the sealing resin from running over.

This can more surely prevent the damages to the laminate structure (cracks of each layer of the laminate structure, especially a semiconductor chip). As a result, it is possible to improve the manufacturing yield of the semiconductor device in which a member of the uppermost section is exposed. Moreover, the mold can be used for long periods, so that the manufacturing cost of the semiconductor device can be reduced.

In the semiconductor device of the present invention, it is preferable that the stress relief section be made from a cushioning material.

The cushioning material, for example, means a material having a property of being deformed so as to absorb a force received from a direction. In other words, the cushioning material may be made of a material at least having flexibility.

Moreover, it is more preferable that in addition to the flexibility, the cushioning material have, for example, a elastic property against a part of the force. That is, it is more preferable that the cushioning material be made of a material having elasticity.

The cushioning material may be, for example, made of a material having flexibility and elasticity such as a polyimide, a solder resist.

When the sealing resin is performed, the stress relief section comes into contact with the mold. Therefore, during resin sealing, an inner surface of the mold is scratched and worn away by coming into contact with the stress relief section. Especially, when the stress relief section is made of a material having a great hardness, which is not easily deformed, the durability of the mold is particularly lowered. For this reason, when the stress relief section is made of the cushioning material, the abrasion of the mold can be prevented. Consequently, the mold can be repeatedly used.

In addition, when the stress relief section is made of the cushioning material, the stress relief section is deformed during resin sealing. This allows partial absorption of the force applied from the upper mold to the laminate structure. Moreover, this allows the stress relief section to more adequately and tightly come into contact with the top surface of the mold. This makes it possible to surely prevent the sealing resin from running over a part in the uppermost section of the laminate structure which part is surrounded by the stress relief section. Accordingly, even if the stress relief section is not exactly in a specified shape due to slight nonevenness of process, intended effects (reduction in the force applied to the entire laminate structure and prevention of the resin from running over) can be expected.

Consequently, this makes it possible to maintain the high manufacturing yield of the semiconductor device in which an uppermost section is exposed with low manufacturing cost and a simple manufacturing process.

In the semiconductor device of the present invention, a member constituting the uppermost section may be a heat sink which radiates heat generated from the semiconductor chip.

With the arrangement, it is possible to manufacture a semiconductor device having a heat sink whose top surface is exposed in the uppermost section of the laminate structure. That is, this allows a semiconductor device to efficiently radiate the heat generated from the semiconductor chip during the operation of the semiconductor device. In addition, it is possible to improve the manufacturing yield of the semiconductor device having the high heat radiation efficiency.

In the semiconductor device of the present invention, a member constituting the uppermost section may be a wiring layer including an external connection terminal, the wiring layer provided on the semiconductor chip.

With the arrangement, it is possible to manufacture a semiconductor device including a wiring layer having an external connection terminal exposed in the sealing resin, the wiring layer provided on the semiconductor chip. This makes it possible to attain a semiconductor device, on which a plurality of semiconductor devices is laminated by connecting another semiconductor device to the exposed external connection terminal. Moreover, it is possible to improve the manufacturing yield of the semiconductor device on which the plurality of semiconductor devices is laminated.

In the semiconductor device of the present invention, a member constituting the uppermost section may be an interposer substrate having an external connection terminal.

With the arrangement, it is possible to manufacture a semiconductor device including an interposer substrate having an external connection terminal exposed in the sealing resin, the interposer substrate provided on the semiconductor chip. This makes it possible to attain a semiconductor device on which a plurality of semiconductor devices is laminated by connecting another semiconductor device to the exposed external connection terminal. Moreover, it is possible to improve the manufacturing yield of the semiconductor device on which the plurality of semiconductor devices is laminated.

In the semiconductor device of the present invention, a member constituting the uppermost section may be a transparent substrate provided on the semiconductor chip.

With the arrangement, it is possible to manufacture a semiconductor device including a transparent substrate which is provided on the semiconductor chip and exposed in the sealing resin. For example, if a light-emitting element and/or a light-receiving element are/is provided on the semiconductor chip, then it is possible to attain a semiconductor device which can be used as a communication tool in an apparatus or a light source of a display device. Moreover, it is possible to improve the manufacturing yield of the semiconductor device including the light-emitting element and/or light-receiving element.

In the semiconductor device of the present invention, a member constituting the uppermost section may be the semiconductor chip.

With the arrangement, it is possible to manufacture a semiconductor device including an exposed semiconductor chip. Also, it is possible to attain a semiconductor device having a light-receiving element or light-emitting element on the semiconductor chip. For example, if a light-emitting element and/or a light-receiving element are/is provided on the semiconductor chip, then it is possible to attain a semiconductor device which can be used as a communication tool in an apparatus or a light source of a display device. Moreover, it is possible to improve the manufacturing yield of the semiconductor device including the light-emitting element and/or light-receiving element.

[Other Arrangements]

The present invention can be also attained with the following arrangements.

(First Arrangement)

A semiconductor device of the present invention includes: a base substrate; a semiconductor chip electrically connected to the base substrate; and a heat sink, the semiconductor chip and the heat sink being laminated via an adhesion layer and a rigid material, wherein resin sealing is performed so as to expose a top surface of the heat sink, a ring-shaped convex section provided on the heat sink.

(Second Arrangement)

A semiconductor device of the present invention includes: a base substrate; and a semiconductor chip electrically connected to the base substrate, wherein resin sealing is performed so as to expose a top surface of the semiconductor chip, a ring-shaped convex section provided on the semiconductor chip.

(Third Arrangement)

A semiconductor device of the present invention includes: a base substrate; and a semiconductor chip electrically connected to the base substrate, the semiconductor chip including a wiring layer, an external connection terminal provided on a surface of the wiring layer, wherein resin sealing is performed so as to expose the wiring layer, a ring-shaped convex section provided on the wiring layer.

(Fourth Arrangement)

A semiconductor device of the present invention includes: a base substrate; a semiconductor chip electrically connected to the base substrate; and an interposer substrate, the semiconductor chip and the interposer substrate being laminated via an adhesion layer and a rigid material, wherein resin sealing is performed so as to expose a top surface of the interposer substrate, a ring-shaped convex section provided on the interposer substrate.

(Fifth Arrangement)

A semiconductor device of the present invention includes: a base substrate; a semiconductor chip electrically connected to the base material; and a glass plate, the semiconductor chip and the glass plate being laminated via an adhesion layer, wherein resin sealing is performed so as to expose a top surface of the glass plate, a ring-shaped convex section provided on the glass plate.

As described above, the semiconductor device of the present invention includes the stress relief section for relieving the force applied from the mold to the entire laminate structure during resin sealing, and the plain top surface of the stress relief section has an area much smaller than that of the top surface of the uppermost section. Accordingly, this makes it possible to improve the manufacturing yield of the semiconductor device in which a member of the uppermost section is exposed in the sealing resin.

In accordance with the present invention, it is possible to improve the manufacturing yield of the semiconductor device, which is sealed with the sealing resin by the transfer mold technique. This allows the semiconductor device to be applied to most electronics devices. Especially, such semiconductor device is effectively applied to the semiconductor device in which a member of the uppermost section is exposed in the sealing resin. According to the present invention, it is possible to attain a semiconductor device excellent in the heat radiation capability, a semiconductor device having a plurality of laminate structures, and a semiconductor device for transmitting and receiving light.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor device comprising:
a laminate structure, including a semiconductor chip, partially sealed with a resin; and
a stress relief section for relieving a stress during resin sealing, provided as a convex section including a plain top surface on an uppermost section of the laminate structure,
the stress relief section being provided in an annular shape on a peripheral region of the uppermost section so as to come into contact with the sealing resin.

2. The semiconductor device as set forth in claim 1,
wherein a periphery of the uppermost section of the laminate structure is sealed with the resin.

3. The semiconductor device as set forth in claim 1,
wherein another stress relief section is further provided inside the stress relief section provided on the peripheral region of the uppermost section.

4. The semiconductor device as set forth in claim 2,
wherein another stress relief section is further provided inside the stress relief section provided on the peripheral region of the uppermost section.

5. The semiconductor device as set forth in claim 1,
wherein the stress relief section is made of a cushioning material.

6. The semiconductor device as set forth in claim 2,
wherein the stress relief section is made of a cushioning material.

7. The semiconductor device as set forth in claim 3,
wherein the stress relief sections are made of a cushioning material.

8. The semiconductor device as set forth in claim 1,
wherein a member constituting the uppermost section is a heat sink for radiating heat generated from the semiconductor chip.

9. The semiconductor device as set forth in claim 1,
wherein a member constituting the uppermost section is a wiring layer including an external connection terminal, the wring layer provided on the semiconductor chip.

10. The semiconductor device as set forth in claim 1,
wherein a member constituting the uppermost section is an interposer substrate including an external connection terminal.

11. The semiconductor device as set forth in claim 1,
wherein a member constituting the uppermost section is a transparent plate provided on the semiconductor chip.

12. The semiconductor device as set forth in claim 1,
wherein a member constituting the uppermost section is the semiconductor chip.

13. A heat sink comprising,
a convex section, having an annular shape, including a plain top surface, the convex section being provided on a peripheral region of a top surface on the heat sink,
the heat sink constituting an uppermost section of a laminate structure including a semiconductor chip, and radiating heat generated from the semiconductor chip.

14. A semiconductor chip comprising,
a convex section, having an annular shape, including a plain top surface, the convex section being provided on a peripheral region of a top surface of the semiconductor chip,
the semiconductor chip constituting an uppermost section of a laminate structure.

15. A transparent plate comprising,
a convex section, having an annular shape, including a plain top surface, the convex section being provided on a peripheral region of a top surface of the transparent plate,
the transparent plate constituting an uppermost section of a laminate structure including a semiconductor chip.

16. A method for manufacturing a semiconductor device comprising the step of,
sealing a laminate structure with a resin, while a stress relief section comes into contact with a top surface of a room inside a mold, the stress relief section having a plain top surface and being provided in an annular shape on a top surface of the laminate structure so as to come into contact with the resin.
